(19) United States
(12) Patent Application Publication
(10) Pub. No.: US 2015/0333762 A1
(43) Pub. Date: Nov. 19, 2015

(54) Method For Linearization Of The Output Of An Analog-To-Digital Converter And Measuring Instruments Using Such Method

(71) Applicant: MIITORS ApS, Horsens (DK)

(72) Inventors: Jens Drachmann, Viby J (DK); Kresten Helstrup, Hasselager (DK); Thomas Vejlgaard Jensen, Hasselager (DK)

(21) Appl. No.: 14/653,695

(22) PCT Filed: May 28, 2013
(86) PCT No.: PCT/DK2013/050160

§ 371 Date: Jun. 18, 2015

(30) Foreign Application Priority Data
Dec. 18, 2012 (DK) PA 2012 70791

(51) Int. Cl. H03M 1/06; G01K 7/16; H03M 1/12

(52) U.S. Cl. CPC H03M 1/0639; H03M 1/12; H03M 1/1245; G01K 7/16

(57) ABSTRACT

A method for linearization of the output of an analog-to-digital converter (ADC) is disclosed, the method including the steps of creating an analog ADC input signal by combining a substantially constant voltage to be measured with an analog dithering signal, feeding the analog ADC input signal to the ADC, converting it into a sequence of digital signal values, and using the sequence of digital signal values for calculating a single resulting digital value representing the voltage to be measured, wherein the analog dithering signal is arranged so that the analog ADC input signal fed to the ADC causes the output of the ADC to vary over the full output range of the ADC.

### FIELD OF THE INVENTION

The present invention relates to a method for linearization of the output of an analog-to-digital converter, a temperature sensor using such method and a heat consumption meter comprising such temperature sensors.

### BACKGROUND OF THE INVENTION

It is well-known within the art to use analog-to-digital converters (ADCs) to convert input in the form of a continuous physical quantity, such as an electric voltage, to a digital number that represents the amplitude of this quantity. Since the conversion involves quantization of the input, it introduces a small amount of error. Instead of doing a single conversion, an ADC often performs the conversions (“samples” the input) periodically. The result is a sequence of digital values that have converted a continuous-time and continuous-amplitude analog signal to a discrete-time and discrete-amplitude digital signal.

The quantization error of the ADC depends on its resolution, i.e. on the number of discrete values it can produce over the range of analog values which, in turn, is decided by the number of bits used by the ADC for representing each digital value. In practice, however, the resolution of an ADC may be improved significantly using well-known methods, such as oversampling of the analog signal and dithering.

Dither, as known in the art, is a very small amount of random noise (typically white noise), which is added to the input before conversion. Its effect is to cause the state of the least significant bit (LSB) of the ADC output to randomly oscillate between 0 and 1 in the presence of very low levels of input, rather than sticking at a fixed value.

Rather than the signal simply getting cut off altogether at this low level (which is only being quantized to a resolution of 1 bit), it extends the effective range of signals that the ADC can convert, at the expense of a slight increase in noise. Effectively, the quantization error is diffused across a series of noise values. The result is an accurate representation of the signal over time. A suitable filter at the output of the system can thus recover this small signal variation. Thus, the dithering produces results that are more exact than the LSB of the ADC.

All ADCs suffer from non-linearity errors caused by their physical imperfections, causing their output to deviate from a linear function. These errors are typically taken care of through calibration of the systems using the ADCs.

It is important to note that a small amount of dither, as known in the art, can only increase the resolution of an ADC. It cannot improve the integral linearity of the ADC, and thus the absolute accuracy does not necessarily improve.

### SUMMARY OF THE INVENTION

It is an object of the present invention to provide a method for linearization of the output of an ADC so that the need for calibration of the system using the ADC is reduced or even eliminated.

The present invention relates to a method for linearization of the output of an analog-to-digital converter (ADC), said method comprising the steps of creating an analog ADC input signal by combining a substantially constant voltage to be measured with an analog dithering signal, feeding the analog ADC input signal to the ADC for converting it into a sequence of digital signal values, and using the sequence of digital signal values for calculating a single resulting digital value representing the voltage to be measured, wherein the analog dithering signal is arranged so that the analog ADC input signal fed to the ADC causes the output of the ADC to vary over at least 50%, preferably over at least 70%, most preferred over at least 80%, of the full output range of the ADC.

It should be noted that by the expression “substantially constant voltage to be measured” is to be understood that the voltage can be considered constant during the time it takes to perform a measurement and obtain a single resulting digital value representing the voltage to be measured, whereas the voltage may vary from one measurement to another.

By letting the ADC input signal vary over most of the output range of the ADC, the non-linearity of the ADC is substantially eliminated. If measurements are performed over a narrow output range only, as is the case in ADC systems known in the art, the non-linearity error overlaying the resulting digital signal value depends on the position of the narrow range within the full output range of the ADC. With the present invention using very broad output ranges, on the other hand, the non-linearity errors accumulated over most of the full output range are substantially the same for each measurement, resulting in an offset of the single resulting digital value, which does not depend on the voltage to be measured.

In an embodiment of the invention, the sequence of digital signal values for calculating a single resulting digital value comprises at least 100 values, preferably at least 500 values, most preferred at least 1000 values.

A large number of digital signal values (or samples) is needed in order to be able to get the necessary information from the signal for obtaining a significant improvement of the resolution due to the dithering, such as for instance a 16 bit resolution from a 12 bit ADC.

In an embodiment of the invention, the analogue dithering signal consists of at least half a period of a substantially sinusoidal signal.

In an embodiment of the invention, the frequency of the substantially sinusoidal signal is between 50 Hz and 20 kHz, preferably between 200 Hz and 10 kHz, most preferred between 500 Hz and 4 kHz.

The use of sinusoidal signals, especially with frequencies within the specified ranges, has shown to result in a very high degree of linearity of the relation between the voltages to be measured and the single resulting digital values representing these voltages.

In an embodiment of the invention, the analog ADC input signal is created either by adding the analog dithering signal to the voltage to be measured or by subtracting the analog dithering signal from the voltage to be measured.

The preferred method for creating the analog ADC input signal from the voltage to be measured and the analog dithering signal may depend on the type and characteristics of the amplifier circuit used for combining the two signals.

In an embodiment of the invention, the calculation of the resulting digital value representing the voltage to be measured includes an averaging of the sequence of digital signal values from the ADC.

If the analog dithering signal is arranged appropriately, the resulting digital value can be calculated through a simple averaging of the values in the sequence of digital signal values from the ADC.

In an embodiment of the invention, the analog dithering signal is produced using a digital-to-analog converter (DAC).

In an embodiment of the invention, the ADC and the DAC are both arranged within a single common electronic microcontroller circuit.

Many modern microcontroller circuits comprise not only an ADC but also one or more DACs within the same circuit, which is advantageous for obtaining cost- and space-efficient solutions.

In an embodiment of the invention, the microcontroller circuit further comprises a direct memory access module (DMA) arranged to feed data from an electronic memory to the DAC for creation of the analog dithering signal during measurement.

In order to utilize the capacity of the microcontroller optimally, it is advantageous if some of the core functions of the microcontroller can be switched off during measurement. This can be obtained using a DMA module, which is able to feed data from an electronic memory to the DAC even when such core functions are switched off.

In an aspect of the invention, it relates to a temperature sensor using the method described above for representing outputs from one or more temperature-dependent electronic components.

In an embodiment of the invention, the temperature-dependent electronic components include at least one positive temperature coefficient (PTC) resistor and the output therefrom is the voltage across the PTC resistor when a constant and well-defined current runs through the PTC resistor.

Using PTC resistors, such as platinum elements, is advantageous, because there is a very high degree of linearity between the temperature and the voltage across such a resistor with a given current running through the resistor.

In an embodiment of the invention, the resistance of the PTC resistor representing the temperature is calculated from the resulting digital value by linear interpolation between two digital reference values, which reference values are found using the method described above for representing the voltage across two resistors, respectively, each of which has a well-defined resistance and using the same constant and well-defined current as used for measuring the voltage across the PTC resistor.

By finding reference values through measurement across two well-defined resistances just before or after each temperature measurement, it is obtained that no calibration of the temperature sensor is needed, and that the well-defined current only has to be constant during one cycle of finding reference values and the temperature measurement.

It should be noted that, in order to avoid any contribution from the analog dithering signal when making the linear interpolation, it is important that the analog dithering signal is exactly the same for each of the three measurements performed during the same cycle when finding a digital output value of the ADC for the voltages across the two reference resistors and the positive temperature coefficient resistor, respectively.

In an aspect of the invention, it relates to a heat consumption meter comprising one or more temperature sensors as described above and a flow meter, in which heat consumption meter the heat energy extracted from a flow of a fluid, such as district heating water, is calculated from the flow of the fluid and the difference between the temperatures of the incoming fluid and the outgoing fluid, respectively.

In an embodiment of the invention, the flow meter is an ultrasonic flow meter measuring the difference between the transit times of ultrasonic pulses propagating in and against the flow direction, respectively.

### BRIEF DESCRIPTION OF THE DRAWINGS

In the following, a few exemplary embodiments of the invention is described in more detail with reference to the figures, of which

FIG. 1 illustrates schematically the non-linearity of an ADC and the consequences thereof when using systems known in the art,

FIG. 2 illustrates schematically the missing consequences of such linearity for a system using a method according to an embodiment of the invention,

FIG. 3 illustrates schematically the configuration of a temperature sensor according to an embodiment of the invention,

FIG. 4 illustrates how the resistance of a temperature dependent resistor can be found by linear interpolation, and

FIG. 5 illustrates schematically the configuration of a heat consumption meter according to an embodiment of the invention.

### DETAILED DESCRIPTION OF THE INVENTION

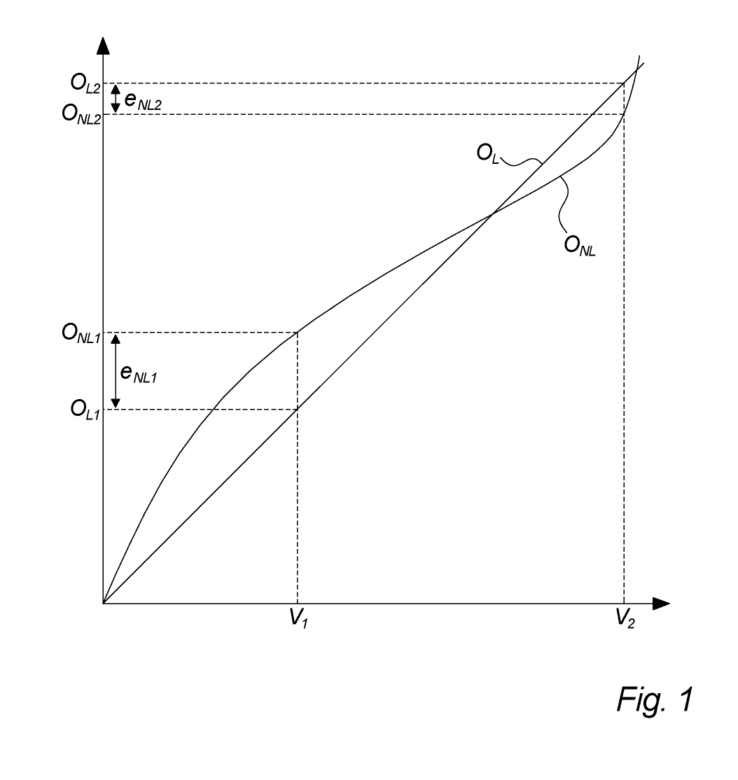

FIG. 1 illustrates schematically the consequences of the non-linearity of an ADC.

With the input on the horizontal input axis and the output on the vertical axis, a linear output curve O_{L} and a non-linear output curve O_{NL} are shown. The figure illustrates, how the non-linearity means that a first input voltage V₁ results in an output O_{NL1}, which is different from the output O_{L1} that would have been the output of a linear ADC. Similarly, a second input voltage V₂ results in an output O_{NL2}, which is different from the output O_{L2} that would have been the output of a linear ADC.

The relations between the actual output values O_{NL1}, O_{NL2} and the ideal output values O_{L1}, O_{L2} are relative simple, as the actual output values O_{NL1}, O_{NL2} are the sums of the ideal output values O_{L1}, O_{L2} and non-linearity error values e_{NL1}, e_{NL2}:

O_{NL1}=O_{L1}+e_{NL1} (1)

O_{NL2}=O_{L2}+e_{NL2} (2)

What should be noted is that the non-linearity error values e_{NL1}, e_{NL2} depend on the input voltages V₁, V₂. Thus for input voltages in a close range around V₁, for instance due to dithering with a small amount of white noise for increasing the resolution as known in the art, the non-linearity error value e_{NL1} is relatively large and positive, whereas for input voltages in a close range around V₂, the non-linearity error value e_{NL1} is relatively small and negative. This means that calibration of the system is needed for taking into account the different non-linearity error values e_{NL1}, e_{NL2} at different input voltages V₁, V₂.

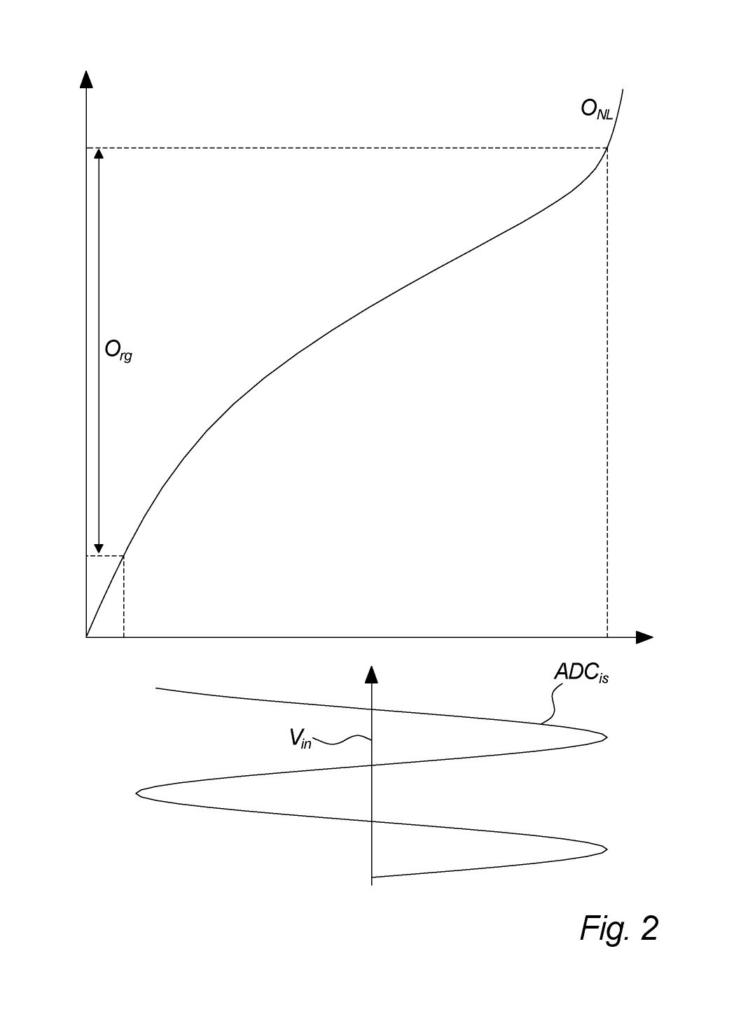

If, on the other hand, as illustrated schematically in FIG. 2, a dithering signal of much larger amplitude than the variations of the input voltage Vᵢₙ is added to or subtracted from the input signal I to form an analog ADC input signal ADCᵢₛ so that the output range O_{rg} corresponding to the analog ADC input signal ADCᵢₛ covers most of the output range of the ADC, the non-linearity errors are accumulated over most of the full output range of the ADC resulting in substantially the same offset added to the output of the ADC for each measurement independent of the input voltage Vᵢₙ.

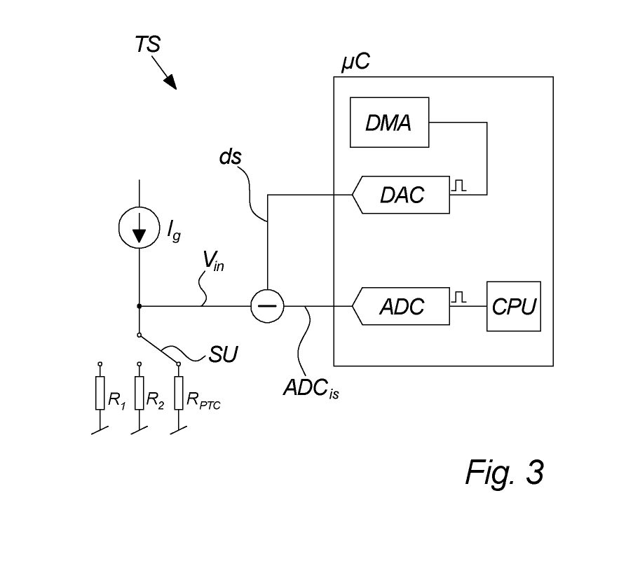

FIG. 3 illustrates schematically the configuration of a temperature sensor TS according to an embodiment of the invention. A constant current generator I_{g} generates an electric current which, through a switching unit SU can be directed through either a first reference resistor R₁, through a second reference resistor R₂ or through a positive temperature coefficient resistor R_{PTC}.

The input voltage Vᵢₙ to be converted by the ADC is measured across the resistor R₁, R₂, R_{PTC} through which this currents runs. Before the input voltage Vᵢₙ is fed to the ADC, however, an analog dithering signal ds with a large amplitude compared to the variations in the input voltage Vᵢₙ as described above is subtracted from the input voltage Vᵢₙ whereby the analog ADC input signal ADCᵢₛ is created.

The analog dithering signal ds, which makes the output from the ADC substantially linear as described above, is created by a digital-to-analog converter DAC, the data for which is provided by a direct memory access module (DMA). The use of a DMA module allows for feeding data to the DAC even when core parts of a microcontroller μC of which the ADC, the DAC and the DMA module are all parts are put out of function. It is advantageous to put those core parts out of function when measuring using the ADC in order to utilize the capacity of the microcontroller μC optimally. Preferably, the dithering signal ds consists of at least half a period of a sinusoidal signal.

The output from the ADC is forwarded to a CPU, which is part of the same microcontroller μC as is the ADC, the DAC and the DMA module, for further processing and calculations. In preferred embodiments, however, a microcontroller μC with an ADC, which is able to perform an averaging of a sequence of samples without involving the CPU, is used. In that case, the whole measuring process can be carried out without any active current consumption by the CPU.

The relation between the resistance of the positive temperature coefficient resistor R_{PTC} of the platinum element type and the temperature follows the “Callendar-Van Dusen” equation.

The simpler form of this equation is generally valid only over the temperature range between 0° C. and 661° C. and is given as:

R(t)=R₀*(1+A*t+B*t²) (3)

In equation (3), the constants A and B are derived from experimentally determined parameters using resistance measurements made at different temperatures.

Solving this simple quadratic equation results in the following value of t:

$$t = \frac{\sqrt{{A}^{2} * {R}_{0}^{2} - 4 * B * {R}_{0}^{2} + 4 * B * R * {R}_{0}} - A * {R}_{0}}{2 * B * {R}_{0}} \qquad ( 4 )$$

Thus, if the actual resistance Ω_{PTC} of R_{PTC} (corresponding to R in equation (4)) is known, the temperature can be calculated from this equation.

Due to the offset added to the output from the ADC because of the use of the dithering signal ds as described above, the simple linear relation between the current running from the constant current generator I_{g} through the positive temperature coefficient resistor R_{PTC} and the output from the ADC according to Ohm's Law is no longer valid.

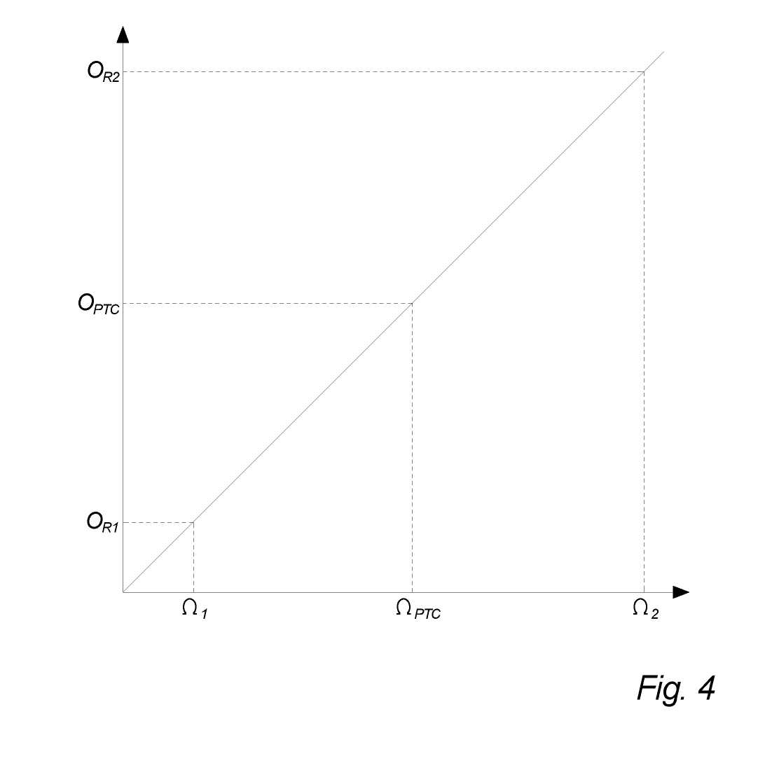

However, taking the substantial linearity of the ADC into account, the actual resistance Ω_{PTC} of R_{PTC} can be calculated by simple linear interpolation if the two reference resistors R₁ and R₂ are chosen to have resistances just outside the resistance range of the positive temperature coefficient resistor R_{PTC} corresponding to the relevant temperature range. Making three subsequent measurements with the three resistors R₁, R₂ and R_{PTC}, respectively, using the same value of the current from the constant current generator I_{g} results in three output values O_{R1}, O_{R2} og O_{PTC}, respectively, from the ADC, the latter being between the two first ones as illustrated in FIG. 4.

If Ω_{R1}, Ω_{R2} og Ω_{PTC} denote the resistances of the three resistors R₁, R₂ and R_{PTC}, respectively, the resistance Ω_{PTC} of the positive temperature coefficient resistor R_{PTC} can be found using the following equation:

$${Ω}_{PTC} = {Ω}_{1} + ( {Ω}_{2} - {Ω}_{1} ) * ( \frac{{O}_{PTC} - {O}_{R 1}}{{O}_{R 2} - {O}_{R 1}} ) \qquad ( 5 )$$

and the temperature can be calculated using equation (4) by substituting Ω_{PTC} for the value R therein.

In some embodiments, the temperature sensor TS comprises more than one positive temperature coefficient resistor R_{PTC} and, optionally, also more than one set of reference resistors R₁. R₂ so that temperatures at different positions can be measured using the same microcontroller μC.

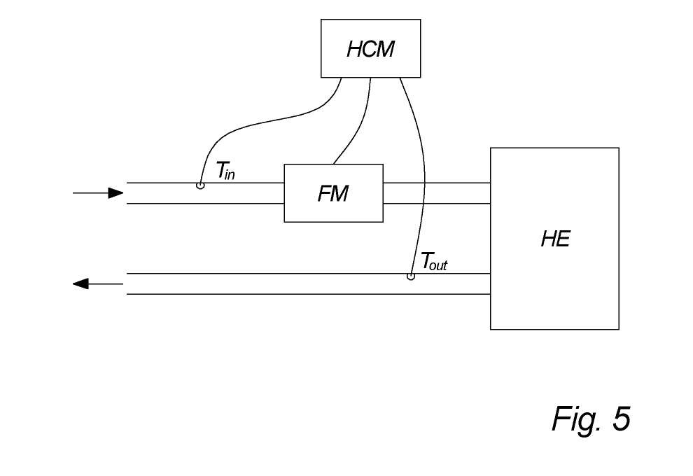

The configuration of a heat consumption meter HCM comprising one or more such temperature sensors TS is illustrated schematically in FIG. 5.

The illustrated heat consumption meter HCM calculates the heat consumption of a heat exchanger HE in a domestic household connected to a district heating system from repeated measurements of the temperatures Tᵢₙ and Tₒᵤₜ of the incoming and outgoing district heating water, respectively, and of the flow of district heating water through the system. The two temperatures Tᵢₙ, Tₒᵤₜ are preferably measured using a temperature sensor TS with two positive temperature coefficient resistors R_{PTC} as described above, whereas the flow of district heating water can be measured using an appropriate flow meter FM, such as an ultrasonic flow meter.

The formulas used by the heat consumption meter HCM for calculating the heat consumption from a sequence of such measured temperature and flow values are well-known within the art and are defined by recognized standards and recommendations relating to heat consumption meters, such as for instance the OIML R 75 recommendation issued by the OIML (International Organization of Legal Metrology).

### LIST OF REFERENCE NUMBERS

ADC. Analog-to-digital converter
ADCᵢₛ. Analog ADC input signal
CPU. Central processing unit
DAC. Digital-to-analog converter
DMA. Direct memory access module
ds. Dithering signal
e_{NL1}. Error value due to non-linearity at a first input voltage
e_{NL2}. Error value due to non-linearity at a second input voltage
FM. Flow meter
HCM. Heat consumption meter
HE. Heat exchanger
I_{g}. Constant current generator
O_{L}. Linear output curve
O_{L1}. Ideal output for a first input voltage
O_{L2}. Ideal output for a second input voltage
O_{NL}. Non-linear output curve
O_{NL1}. Actual output for a first input voltage
O_{NL2}. Actual output for a second input voltage
O_{PTC}. Output using PTC resistor
O_{R1}. Output using first reference resistor
O_{R2}. Output using second reference resistor
O_{rg}. Output range corresponding to analog ADC input signal
R₁. First reference resistor
R₂. Second reference resistor
R_{PTC}. Positive temperature coefficient resistor
SU. Switching unit
Tᵢₙ. Temperature of incoming district heating water
TS. Temperature sensor
Tₒᵤₜ. Temperature of outgoing district heating water
Vᵢₙ. Input voltage
V₁. First input voltage
V₂. Second input voltage
Ω_{PTC}. Resistance of PTC resistor
Ω_{R1}. Resistance of first reference resistor
Ω_{R2}. Resistance of second reference resistor
μC. Electronic microcontroller

1. A method for linearization of an output of an ADC, said method comprising the steps of:
creating an analog ADC input signal by combining a substantially constant voltage to be measured with an analog dithering signal,
feeding the analog ADC input signal to the ADC for converting it into a sequence of digital signal values, and
using the sequence of digital signal values for calculating a single resulting digital value representing the voltage to be measured,
wherein the analog dithering signal is arranged so that the analog ADC input signal fed to the ADC causes an output of the ADC to vary over at least 50% of a full output range of the ADC.

2. The method according to claim 1, wherein the sequence of digital signal values for calculating a single resulting digital value comprises at least 100 values.

3. The method according to claim 1, wherein the analogue dithering signal consists of at least half a period of a substantially sinusoidal signal.

4. The method according to claim 3, wherein a frequency of the substantially sinusoidal signal is between 500 Hz and 4 kHz.

5. The method according to claim 1, wherein the analog ADC input signal is created by adding the analog dithering signal to the voltage to be measured.

6. The method according to claim 1, wherein the calculation of the resulting digital value representing the voltage to be measured includes an averaging of the sequence of digital signal values from the ADC.

7. The method according to claim 1, wherein the analog dithering signal is produced using a DAC.

8. The method according to claim 7, wherein the ADC and the DAC are both arranged within a single common electronic microcontroller circuit.

9. The method according to claim 8, wherein the microcontroller circuit further comprises a direct memory access module arranged to feed data from an electronic memory to the DAC for creation of the analog dithering signal during measurement.

10. A temperature sensor comprising an ADC and being arranged to establish a linearized output of the ADC for representing outputs from one or more temperature-dependent electronic components, wherein
the temperature sensor is arranged to create analog ADC input signal by combining a substantially constant voltage to be measured with an analog dithering signal,
the temperature sensor is arranged to feed the analog ADC input signal to the ADC for converting it into a sequence of digital signal values, and
the temperature sensor is arranged to calculate a single resulting digital value representing the voltage to be measured from the sequence of digital signal values; and
wherein the analog dithering signal is arranged so that the analog ADC input signal fed to the ADC causes an output of the ADC to vary over at least 50% of a full output range of the ADC.

11. The temperature sensor according to claim 10, wherein the one or more temperature-dependent electronic components include at least one positive temperature coefficient resistor and an output therefrom corresponds to a voltage across the PTC resistor when a constant and well-defined current runs through the PTC resistor.

12. The temperature sensor according to claim 11, wherein a resistance of the PTC resistor representing a temperature is calculated from the resulting digital value by linear interpolation between two digital reference values said reference values representing the voltage across two resistors, respectively, each of which has a well-defined resistance and using the same constant and well-defined current as used for measuring the voltage across the PTC resistor.

13. A heat consumption meter comprising one or more temperature sensors according to claim 10 and a flow meter, in which heat consumption meter a heat energy extracted from a flow of a fluid, such as district heating water, is calculated from the flow of the fluid and a difference between temperatures of an incoming fluid and an outgoing fluid, respectively.

14. A heat consumption meter according to claim 13, wherein the flow meter is an ultrasonic flow meter measuring a difference between transit times of ultrasonic pulses propagating along and against a flow direction, respectively.

15. The method of claim 1, wherein the analog dithering signal is arranged so that the analog ADC input signal fed to the ADC causes an output of the ADC to vary over at least 70% of a full output range of the ADC.

16. The method of claim 1, wherein the analog dithering signal is arranged so that the analog ADC input signal fed to the ADC causes an output of the ADC to vary over at least 80% of a full output range of the ADC.

17. The method of claim 1, wherein the sequence of digital signal values for calculating a single resulting digital value comprises at least 500 values.

18. The method of claim 1, wherein the sequence of digital signal values for calculating a single resulting digital value comprises at least 1000 values.

19. The method of claim 3, wherein a frequency of the substantially sinusoidal signal is between 200 Hz and 10 kHz.

20. The method of claim 3, wherein a frequency of the substantially sinusoidal signal is between 500 Hz and 4 kHz.

21. The method of claim 1, wherein the analog ADC input signal is created by subtracting the analog dithering signal from the voltage to be measured.

22. The method of claim 9, wherein the ADC is arranged to perform an averaging of the sequence of digital signal values from the ADC.

23. A method for determining a resistance of a PTC resistor, the method comprising:
providing two resistors with pre-determined, different resistances;
applying a constant and well-defined current to each of the two resistors;
for each of the two resistors, creating a reference digital representation of a voltage across the respective resistor using an ADC;
applying the constant and well-defined current to the PTC resistor;
creating a digital representation of a voltage across the PTC resistor using the ADC;
determining the resistance of the PTC resistor using linear interpolation between the two reference digital representations.

24. The method of claim 23, wherein the reference digital representations and the digital representation are created using the ADC according to a method of linearizing an output of the ADC comprising the steps of:
creating an analog ADC input signal by combining a voltage across a resistor or PTC resistor to be measured with an analog dithering signal;
converting the analog ADC input signal into a sequence of digital signal values using the ADC; and
calculating a single resulting digital value representing the voltage across the resistor or PTC resistor to be measured from the sequence of digital signal values;
wherein the analog dithering signal is arranged so that the analog ADC input signal fed to the ADC causes the sequence of digital signal values to vary over at least 50% of a full output range of the ADC.
